(19) United States
(12) Patent Application Publication
(10) Pub. No.: US 2007/0241429 A1
(43) Pub. Date: Oct. 18, 2007

(54) ELECTRICALLY CONDUCTING TRACK AND METHOD OF MANUFACTURE THEREOF

(75) Inventors: Ron Arnold, Milton Keynes (GB); John Stephen Atherton, Darlington (GB); Nigel Cameron, Darlington (GB); Matthew Francis O'Keefe, Aycliffe (GB)

Correspondence Address: HOWARD & HOWARD ATTORNEYS, P.C., THE PINEHURST OFFICE CENTER, SUITE #101, 39400 WOODWARD AVENUE, BLOOMFIELD HILLS, MI, 48304-5151, US

(73) Assignee: FILTRONIC COMPOUND SEMICONDUCTORS LIMITED, Co Durham (GB)

(21) Appl. No.: 11/736,910

(22) Filed: Apr. 18, 2007

(30) Foreign Application Priority Data
Apr. 18, 2006 (GB) 0607628.5

(51) Int. Cl. H01L 23/58

(52) U.S. Cl. 257/630

(57) ABSTRACT

An electrically conducting track comprising
an electrically conducting track layer;
a semiconductor substrate; and
a dielectric layer sandwiched between track layer and semiconductor substrate;
the electrically conducting track further comprising an electrically conducting resistor track between semiconductor substrate and dielectric layer

The present invention relates to an electrically conducting track and a method of manufacture thereof. More particularly, but not exclusively, the present invention relates to a bond pad comprising a dielectric layer on a semiconductor substrate having an electrically conductive resistor track sandwiched there between. The bond pad further comprises an electrically conducting bond pad layer on the dielectric layer.

Semiconductor substrate space is at a premium in modern semiconductor device manufacture. Modern semiconductor devices however tend to be laid out in a planar fashion with all the components on the surface of the substrate. Resistors are laid out as thin resistor tracks on the surface of the substrate which take up a large area of substrate. Semiconductor devices which include a large number of resistors tend to be inherently large structures.

The present invention seeks to overcome this problem.

Accordingly, in a first aspect, the present invention provides an electrically conducting track comprising
an electrically conducting track layer;
a semiconductor substrate; and
a dielectric layer sandwiched between track layer and semiconductor substrate;
the electrically conducting track further comprising an electrically conducting resistor track between semiconductor substrate and dielectric layer.

By stacking the resistor track below the electrically conducting track layer in this way one considerably reduces the amount of semiconductor substrate required to manufacture a circuit.

The track layer can be a bond pad.

Preferably, the track layer is a metal.

The resistor track can be a serpentine track comprising at least one bend.

Preferably, the resistivity of the resistor track is at least an order of magnitude less than that of the semiconductor substrate.

The resistor track can comprise a metal film on the semiconductor substrate.

Preferably, the resistivity of the resistor track is less than 300 ohms per square, preferably less than 200 ohms per square.

Alternatively, the resistor track comprises a semiconductor resistor track.

Preferably, the thickness of the resistor track is less than 300 microns, preferably less than 200 microns.

The substrate can be GaAs. Alternatively, the substrate can be Silicon.

The dielectric can be SiN.

Preferably, the electrically conducting track can comprise a plurality of resistor tracks between the semiconductor substrate and dielectric layer.

In a further aspect of the invention there is provided a method of manufacture of an electrically conducting track comprising the steps of
providing a semiconductor substrate;
providing an electrically conducting resistor track on the substrate;
providing a dielectric on the substrate and resistor track; and,
providing an electrically conducting track layer on the dielectric.

The step of providing an electrically conducting resistor track can comprise the step of depositing a metal film on the semiconductor substrate.

Alternatively, the step of providing a resistor track can comprise the step of doping a portion of an upper layer of the semiconductor substrate to improve its conductivity, the doped portion of the semiconductor substrate defining the resistor track.

In a further alternative, the step of providing a resistor track can comprise the steps of doping an upper layer of the semiconductor substrate to increase its electrical conductivity, reducing the conductivity of a portion of the upper layer by ion implantation, the remaining portion of the upper layer defining the resistor track.

The resistor track can be serpentine, comprising at least one bend.

The track layer can be a bond pad. The track layer can be a metal.

The present invention will now be described by way of example only and not in any limitative sense, with reference to the accompanying drawings in which

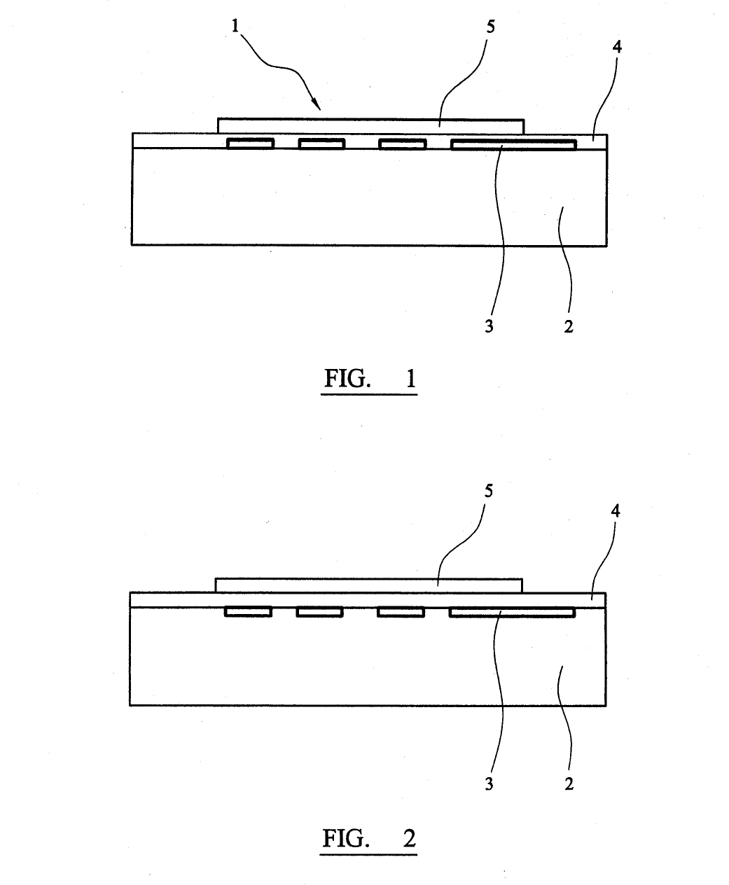

FIG. 1 shows a first embodiment of a bond pad according to the invention in cross section;

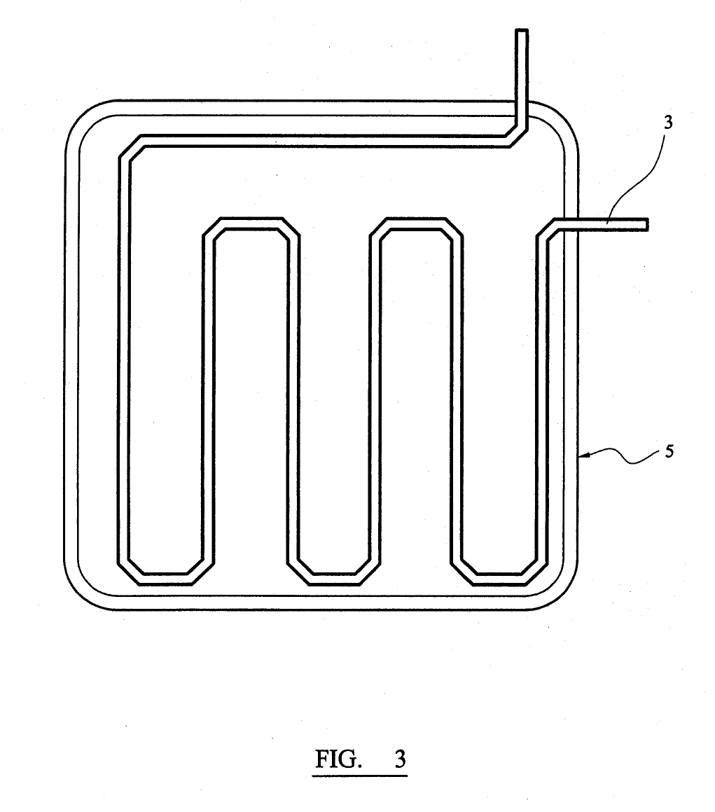

FIG. 2 shows a second embodiment of a bond pad according to the invention; and

FIG. 3 shows a bond pad according to the invention in plan view.

Shown in FIG. 1 is an electrically conducting track 1 according to the invention. The electrically conducting track 1 comprises a GaAs semiconductor substrate 2. Located on the substrate 2 is a serpentine metal resistor track 3 arranged such that the resistance between the opposite ends of the track 3 has a desired value. Covering the resistor track 3 is a dielectric layer 4. An electrically conducting track layer comprising a metal bond pad layer 5 is positioned on the dielectric layer 4.

The electrically conducting track 1 according to the invention is manufactured by depositing the metal resistor track 3 on the substrate 2. This is then covered by the dielectric layer 4. Finally, the bond pad layer 5 is laid down on the dielectric layer 4. The dielectric layer 4 is SiN having a dielectric constant in the range 6-7.5. The resistor track 3 is a thin film having a resistivity around 200 Ohms/Square and a typical thickness in the range 1-200 microns. The bulk resistivity of the metal of the resistor track 3 is substantially less (at least an order of magnitude) than that of the surrounding substrate 2.

In an alternative embodiment the substrate 2 is silicon. Silicon however has a relatively high conductivity and so must be pre-treated (typically by doping or ion implantation) to ensure its electrical resistivity is substantially higher than that of the resistor track 3 material.

Shown in FIG. 2 is a second embodiment of a electrically conducting track 1 according to the invention. The electrically conducting track 1 comprises a GaAs semiconductor substrate 2 having a semiconductor resistor track 3 thereon.

The top face of the resistor track 3 is co-planar with the top face of the substrate 2. Laid down on top of the substrate 2 and resistive track 3 is a dielectric layer 4. On top of this is an electrically conductive bond pad 5.

According to a first method of manufacture of the electrically conducting track of FIG. 2 an upper layer of the GaAs substrate 2 is doped to produce an upper layer (not shown) having improved electrical conductivity. A portion of this upper layer then has its conductivity reduced by ion implantation. The remaining portion of the upper layer defines the resistor track 3. The ion implantation reduces the bulk electrical conductivity of the semiconductor material surrounding the resistor track 3 to at least an order of magnitude less than that of the material of the resistor track 3. The resistor track 3 is then covered with the dielectric layer 4. The conductive bond pad layer 5 is then deposited on the dielectric layer 4.

In an alternative method of manufacture of the electrically conducting track of FIG. 2, a portion of the upper layer of the substrate 2 is doped directly to increase its electrical conductivity to define the resistor track 3. The substrate 2 and track 3 are again covered with a dielectric layer 4 and then a bond pad layer 5.

Shown in FIG. 3 is the electrically conducting track according to the invention in plan view. As can be seen, the resistor track 3 is a serpentine track including a plurality of bends beneath the bond pad 5 to increase its length. The ends of the resistor track 3 extend beyond the bond pad 5 to allow easy connection to the resistor track 3.

In the embodiments of FIGS. 1 to 3 the track layer is a bond pad. In alternative embodiments of the invention the track layer could comprise an alternative electrically conducting track.

In a further embodiment of the invention the electrically conducting track according to the invention comprises a plurality of resistor tracks between the semiconductor substrate and dielectric layer.

1. An electrically conducting track comprising:
an electrically conducting track layer;
a semiconductor substrate; and
a dielectric layer sandwiched between the electrically conducting track layer and the semiconductor substrate;
the electrically conducting track layer further comprising an electrically conducting resistor track between the semiconductor substrate and the dielectric layer.

2. An electrically conducting track as claimed in claim 1, wherein the electrically conducting track layer is a bond pad.

3. An electrically conducting track as claimed in claim 1, wherein the electrically conducting track layer is a metal.

4. An electrically conducting track as claimed in claim 1, wherein the electrically conducting resistor track is a serpentine track comprising at least one bend.

5. An electrically conducting track as claimed in claim 1, wherein the resistivity of the electrically conducting resistor track is at least an order of magnitude less than that of the semiconductor substrate.

6. An electrically conducting track as claimed in claim 5, wherein the electrically conducting resistor track comprises a metal film on the semiconductor substrate.

7. An electrically conducting track as claimed in claim 6, wherein the resistivity of the electrically conducting resistor track is less than 300 ohms per square, preferably less than 200 ohms per square.

8. An electrically conducting track as claimed in claim 5, wherein the electrically conducting resistor track comprises a semiconductor resistor track.

9. An electrically conducting track as claimed in claim 1, wherein the thickness of the electrically conducting resistor track is less than 300 microns, preferably less than 200 microns.

10. An electrically conducting track as claimed in claim 1, wherein the semiconductor substrate is GaAs.

11. An electrically conducting track as claimed in claim 1, wherein the semiconductor substrate is Si.

12. An electrically conducting track as claimed in claim 1, wherein the dielectric layer is SiN.

13. An electrically conducting track as claimed in claim 1 comprising a plurality of resistor tracks between the semiconductor substrate and the dielectric layer.

14. A method of manufacture of an electrically conducting track comprising the steps of:
providing a semiconductor substrate;
providing an electrically conducting resistor track on the semiconductor substrate;
providing a dielectric layer on the semiconductor substrate and the resistor track; and
providing an electrically conducting track layer on the dielectric layer.

15. A method as claimed in claim 14, wherein the step of providing an electrically conducting resistor track comprises the step of depositing a metal film on the semiconductor substrate.

16. A method as claimed in claim 14, wherein the step of providing a resistor track comprises the step of doping a portion of an upper layer of the semiconductor substrate to improve conductivity of the semiconductor substrate, the doped portion of the semiconductor substrate defining the resistor track.

17. A method as claimed in claim 14, wherein the step of providing a resistor track comprises the steps of doping an upper layer of the semiconductor substrate to increase electrical conductivity of the semiconductor substrate, reducing the conductivity of a portion of the upper layer by ion implantation, the remaining portion of the upper layer defining the resistor track.

18. A method as claimed in claim 14, wherein the resistor track is serpentine, comprising at least one bend.

19. A method as claimed in claim 14, wherein the track layer is a bond pad.

20. A method as claimed in claim 14, wherein the track layer is a metal.

21. (canceled)

22. (canceled)

23. (canceled)
